(19) United States
(12) Patent Application Publication
(10) Pub. No.: US 2004/0105243 A1
(43) Pub. Date: Jun. 3, 2004

(54) ELECTRONIC DEVICE HAVING A PLURALITY OF METALLIC BALLS FOR TRANSMITTING SIGNALS BETWEEN TWO CIRCUIT BOARDS

(76) Inventors: Kuang-Hua Lee, Tao-Yuan Hsien (TW); Sea-Weng Young, Ping-Tung Hsien (TW)

Correspondence Address: NAIPO (NORTH AMERICA INTERNATIONAL PATENT OFFICE), P.O. BOX 506, MERRIFIELD, VA, 22116, US

(21) Appl. No.: 10/605,479

(22) Filed: Oct. 2, 2003

(30) Foreign Application Priority Data
Oct. 3, 2002 (TW) 091122919

(51) Int. Cl. H05K 1/11; H05K 1/14

(52) U.S. Cl. 361/792

(57) ABSTRACT

An electronic device includes a primary circuit board, a secondary circuit board, and a plurality of metallic balls electrically connected between the primary circuit board and the secondary circuit board for transmitting signals between the primary circuit board and the secondary circuit board.

### BACKGROUND OF INVENTION

1. Field of the Invention

The present invention relates to an electronic device, more specifically, to an electronic device having a plurality of metallic balls for transmitting signals between two circuit boards and a method for making such device.

2. Description of the Prior Art

With the fast development of electronics technology, most electronic devices are not made up of electronic components individually, but of electronic modules providing different functions. Electronic devices being composed of electronic modules not only lowers the cost of these electronic devices, but improves the quality of these electronic devices because the electrical contacts of these electronic devices are fewer than those composed of individual electronic components. Typically, electronic devices comprise a lot of electronic modules providing different functions, so they need different connectors for transmitting signals between electronic modules.

Please refer to FIG. 1. FIG. 1 is a schematic diagram of a conventional electronic device 10. The electronic device 10 comprises a primary circuit board 12, a secondary circuit board 14, a plurality of electronic components 16 set on the primary circuit board 12, a plurality of electronic components 18 set on the secondary circuit board 14, a male connector 20 set on the primary circuit board 12, and a female connector 22 set on the secondary circuit board 14. The male connector 20 comprises a plurality of input/output ends 24, and the female connector 22 also comprises a plurality of input/output ends 26 corresponding to the input/output ends 24. The input/output ends 24 of the male connector 20 and the input/output ends 26 of the female connector 22 are used for transmitting signals between the plurality of electronic components 16 set on the primary circuit board 12 and the plurality of electronic components 18 set on the secondary circuit board 14.

For example, the electronic device 10 is a cellular phone. An input/output module is composed of the primary circuit board 12, the plurality of electronic components 16 set on the primary circuit board 12, and the male connector 20. A communication module is composed of the secondary circuit board 14, the plurality of electronic components 18 set on the secondary circuit board 14, and the female connector 22. The plurality of electronic components 16 set on the primary circuit board 12 are common input/output electronic components of the input/output module, such as pushbuttons, amplifier systems, and liquid crystal displays (LCDs). The plurality of electronic components 18 set on the secondary circuit board 14 are necessary electronic components of the communication module, such as RF circuits and baseband circuits. A user can use the cellular phone by pushing the pushbuttons and reading messages received by the communication module through the amplifier systems and LCDs in the input/output module. Because the communication module and input/output module are both mature electronic modules, meaning the qualities of the two modules are quite steady, new electrical contacts in the cellular phone only appear between the plurality of input/output ends 26 of the female connector 22 in the communication module and the plurality of input/output ends 24 of the male connector 20 in the input/output module. Therefore, as long as we control the qualities of these few new electrical contacts, we can ensure the quality of the assembled cellular phone.

Not only the electronic device 10 composed of modular components has the abovementioned advantage; the electronic device 10 can also be composed of other kinds of electronic modules. Respective connectors transmit the signals between the communication module and the input/output module in the cellular phone so the female connector 22 in the communication module is easily plugged into the male connector 20 of the input/output module. Manufacturers of cellular phones are able to assemble the communication modules and other input/output modules, or the input/output modules and other communication modules having different communication functions, to fit the diverse needs of the market.

The conventional electronic device 10 composed of the electronic modules with connectors is easy to assemble, however, the conventional electronic device 10 has at least the following defects:

1)The thicknesses of the male connector 20 and the female connector 22 electrically connecting the primary circuit board 12 and the secondary circuit board 14 typically exceeds 4 mm., and this thickness increases when including the pins of the connectors. The size of the electronic device 10 including the connectors is difficult to reduce. This does not meet the basic needs of lightness, thinness, and compactness for modern electronic devices.

2)With complicated circuit designs, the number of input/output ends for all kinds of electronic modules increase dramatically. A single-line male connector 20 and female connector 22 on the primary circuit board 12 and secondary circuit board 14 are often inadequate and replaced with a rectangular array of embedded connectors for enough input/output ends. When the need of input/output ends of electronic modules is further increased, the rectangular array of embedded connectors are inadequate, and the only solution is to enlarge the size of circuit boards. However, this does not meet the basic needs of lightness, thinness, and compactness for modern electronic devices, either.

3)Connectors, especially a rectangular array of embedded connectors, increase the cost and weight of the electronic device 10.

4)Generally speaking, most electronic devices have to be made through the procedure of high temperature fusing in a reflow oven. The circuits in the electronic modules cannot stand long-time and multiple procedures of high temperature fusing, that is they cannot be kept flat after experiencing such procedures. The rigidity of the circuit boards results in solder cracks between the connector and the circuit board and further leads to a poor and intermittent electrical connections between electronic modules.

### SUMMARY OF INVENTION

It is therefore a primary objective of the claimed invention to solve the above-mentioned problems by providing an electronic device having a plurality of metallic balls set on a circuit board in an electronic module to connect circuit boards.

The claimed invention electronic device includes a primary circuit board, a secondary circuit board fixed on the primary circuit board, and a plurality of metallic balls electrically connected between the primary circuit board and the secondary circuit board for transmitting signals between the primary circuit board and the secondary circuit board.

The plurality of metallic ballsin the claimed invention electronic device is adhered to the secondary circuit board by a thin layer of adhesive, welded on the secondary circuit board after passing through a reflow oven. The secondary circuit board is connected with the primary circuit board through the procedure of melting and solidification. The secondary circuit board further comprises a metallic frame and a metallic shielding cap both for preventing the electronic components on the secondary circuit board from being interfered with by other signals or electromagnetic radiation when operating.

These and other objectives of the claimed invention will no doubt become obvious to those of ordinary skill in the art after reading the following detailed description of the preferred embodiment that is illustrated in the various figures and drawings.

### BRIEF DESCRIPTION OF DRAWINGS

FIG. 1 is a schematic diagram of a conventional modular electronic device.

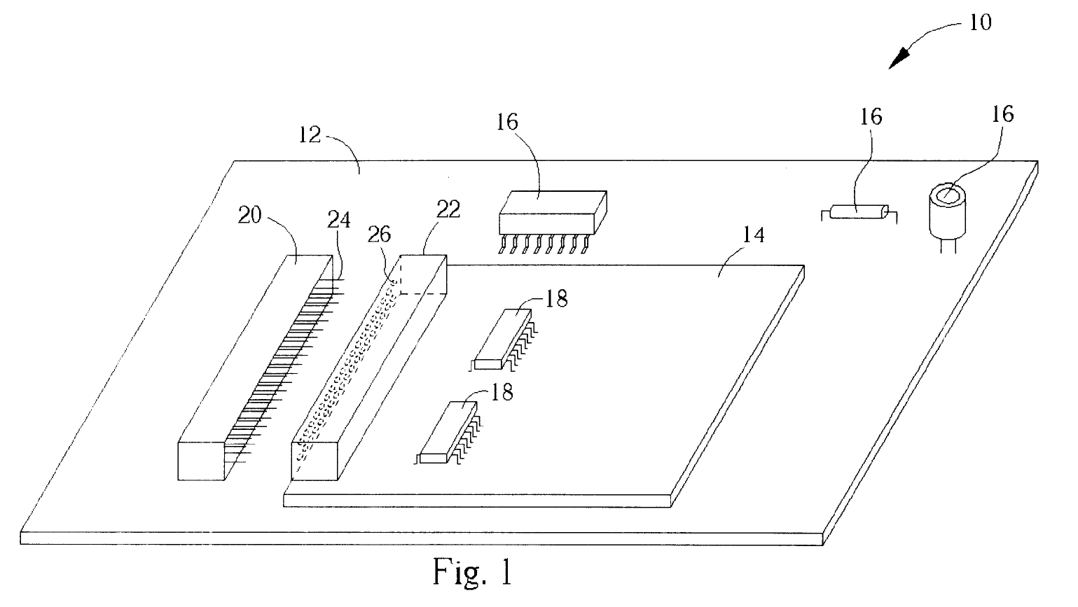

FIG. 2 is a schematic diagram of an electronic device according to the present invention.

FIG. 3 is a side view of the electronic device of FIG. 2.

FIG. 4 is a bottom view of the secondary circuit board of FIG. 2.

FIG. 5 is a diagram showing a relationship between temperature and time in a reflow oven according to the present invention.

FIG. 6 is a flow chart of a method of connecting a circuit board with another circuit board by a plurality of metallic balls according to the present invention.

### DETAILED DESCRIPTION

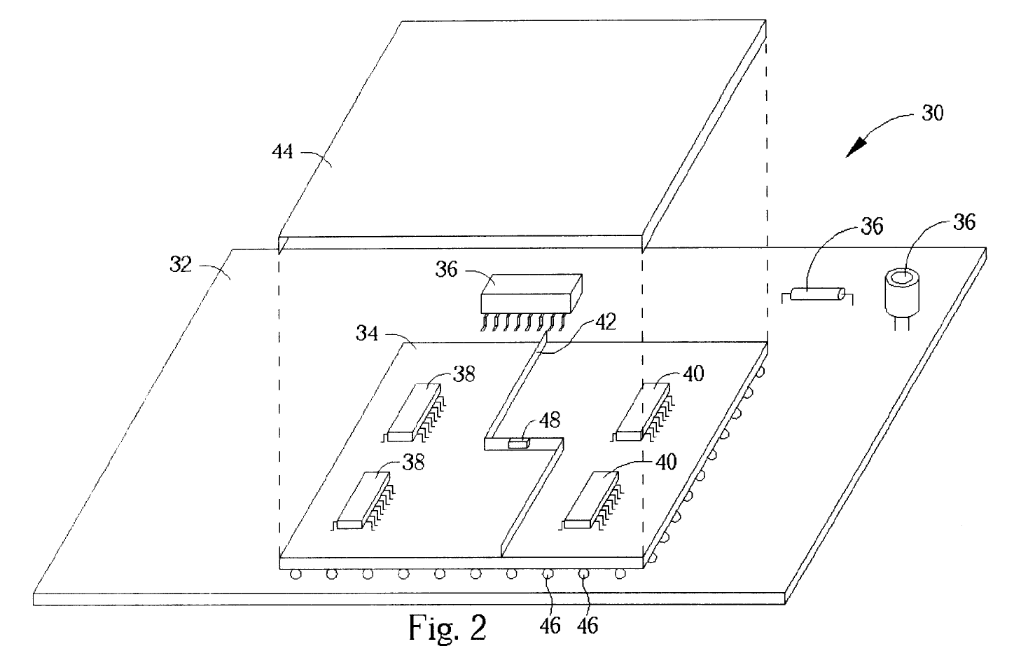

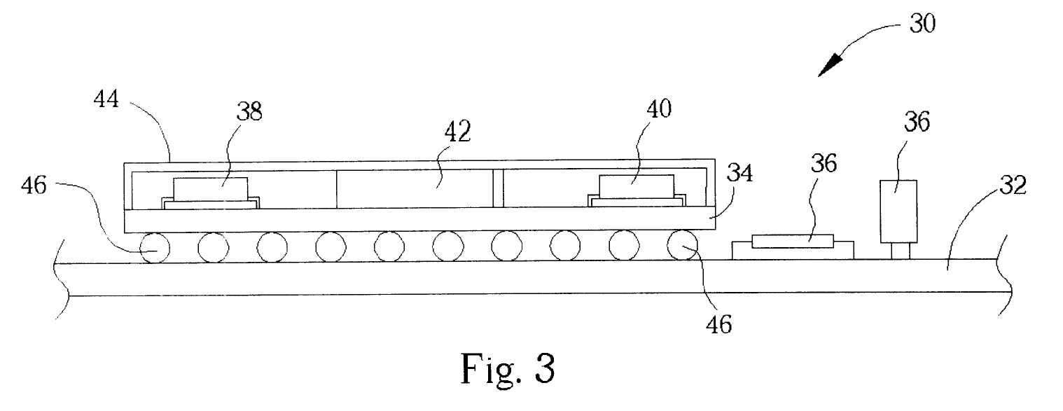

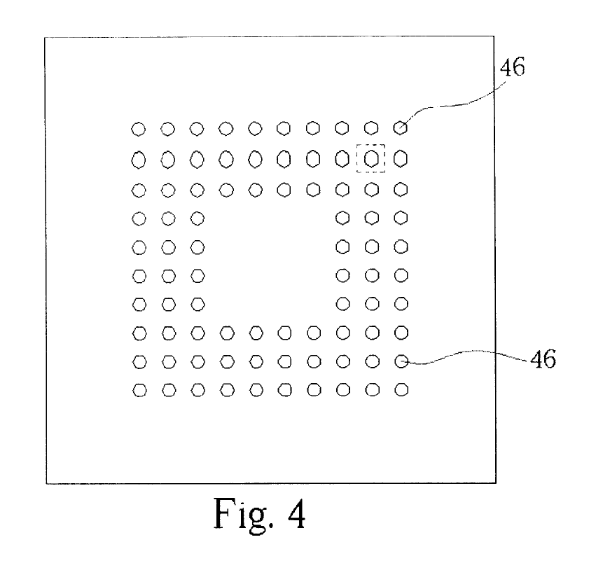

Please refer to FIG. 2, FIG. 3, and FIG. 4. FIG. 2 is a schematic diagram of an electronic device 30 according to the present invention. The electronic device 30 includes a primary circuit board 32 and a secondary circuit board 34, wherein these two circuit boards can be printed circuit boards. FIG. 3 is a side view of the electronic device 30. FIG. 4 is a bottom view of the secondary circuit board 34 in the electronic device 30. A plurality of electronic components 36 is set on the primary circuit board 32 in the electronic device 30. The secondary circuit board 34 of the electronic device 30 comprises a plurality of digital electronic components 38 for receiving and transmitting digital signals, a plurality of analog electronic components 40 for receiving and transmitting analog signals, a metallic frame 42 having a shape that comprises two substantially parallel line segments joined at corresponding ends by a line segment that is substantially perpendicular to the two parallel line segments, and a metallic shielding cap 44. The metallic shielding cap 44 covers the secondary circuit board 34 for shielding the pluralities of electronic components 38, 40 on the secondary circuit board 34 to prevent the pluralities of electronic components from being interfered with by electromagnetic radiation. The pluralities of electronic components 38, 40 could be set on the secondary circuit board 34 by means of surface mount technology (SMT). The metallic frame 42 is set between the plurality of digital electronic components 38 and the plurality of analog electronic components 40, and its top bonds to the metallic shielding cap 44. The digital and analog signals respectively from the two different types of the electronic components are separated by the metallic frame 42 to prevent the digital electronic components 38 and the analog electronic components 40 from mutually interfering when operating. The shape of the metallic frame 42 helps the metallic frame 42 to stand in a self-supporting manner on the secondary circuit board 34. A protrusion 48 is positioned on one side of the metallic frame 42 and is used to hold the metallic frame 42 during manufacture.

Please refer to FIG. 3 and FIG. 4. A plurality of metallic balls 46 electrically connecting a bottom surface of the primary circuit board 32 and a top surface of the secondary circuit board 34 (the connecting way is illustrated afterward) is used to transmit signals between the primary circuit board 32 and the secondary circuit board 34. The metallic balls 46 are made of a eutectic tin ball having a ratio of tin to lead of 63:47, or can be made of other elements.

The electronic device 30 could be a cellular phone, a PDA, or a notebook computer. For instance, an input/output module is composed of the primary circuit board 32 and the plurality of electronic components 36 on the primary circuit board 32. A communication module is composed of the secondary circuit board 34, the pluralities of electronic components 38, 40 on the secondary circuit board 34, the metallic frame 42 on the secondary circuit board 34, the metallic shielding cap 44, and the plurality of metallic balls 46.

In the preferred embodiment of the present invention, the electronic device 30 is a cellular phone. A communication module is composed of the secondary circuit board 34, the plurality of digital electronic components 38, the plurality of analog electronic components 40, the metallic frame 42, the metallic shielding cap 44, and the plurality of metallic balls 46. The plurality of digital electronic components 38 comprises a digital signal processor (DSP), a microprocessor, an ADC/DAC, a memory, and so on for a baseband circuit. The plurality of analog electronic components 40 comprises a transceiver, a power control (PA), a T/R switch, and so on for an RF circuit. The number of the metallic balls is not less than 145. An input/output module is composed of the primary circuit board 32 and the plurality of electronic components 36 on the primary circuit board 32. The metallic balls 46 are adhered to the secondary circuit board 34 by a thin layer of an adhesive such as a flux. A method of connecting the primary circuit board 32 being the input/output module and the secondary circuit board 34 being the communication module by the plurality of metallic balls 46 is as follows. First, the communication module adhered to the plurality of metallic balls 46 is set in a heating apparatus like a reflow oven, where the temperature is adjusted according to a relationship between temperature and time. After the plurality of metallic balls 46 melts and solidifies quickly, the communication module is taken out from the reflow oven and placed correspondingly on the input/output module. Then the communication module and input/output module are together positioned in the reflow oven. After the plurality of metallic balls 46 on the communication module melts and solidifies, the communication module is connected with the input/output module by the plurality of metallic balls 46.

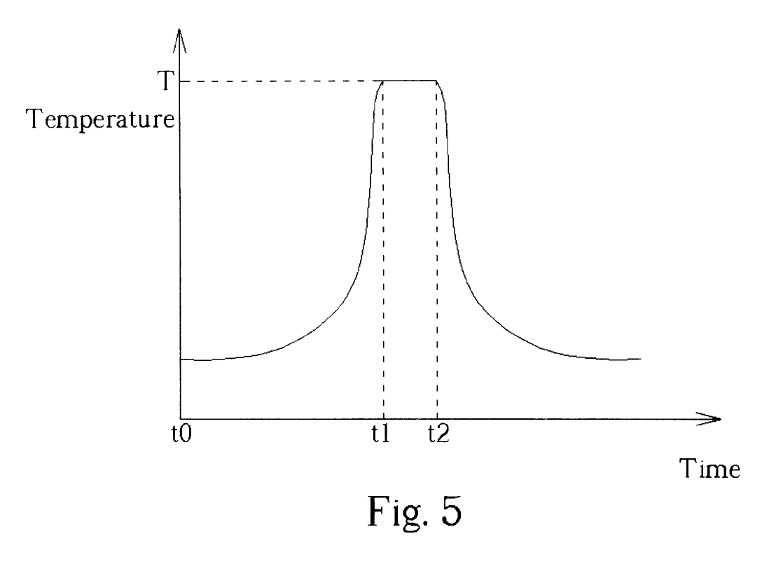

Please refer to FIG. 5. FIG. 5 is a diagram showing a relationship between temperature and time. The plurality of metallic balls 46 and the communication module not permanently connected with the plurality of metallic balls 46 are set in the reflow oven at a time t0. During a period of time the temperature in the reflow oven is gradually increased, and moisture in the electronic components in the communication module gradually decreases. At a time t1, the temperature in the reflow oven rapidly rises to a temperature T, the eutectic melting point of tin and lead of the metallic solder balls 46. In other words, when the temperature in the reflow oven reaches the temperature T (about 220-240 centigrade), the plurality of metallic balls 46 in the communication module melts completely. The temperature in the reflow oven is then kept at the temperature T for a period (about 5-10 seconds depending on the type of reflow oven). At a time t2, the temperature in the reflow oven is decreased quickly to solidify the melted plurality of metallic balls 46, and the plurality of metallic balls 46 becomes tightly connected with the communication module. Then, the communication module connected with the plurality of metallic balls 46 is combined with the input/output module according to the aforesaid procedure. After the communication module is connected with the input/output module by the plurality of metallic balls 46, even if the primary circuit board 32 and the secondary circuit board 34 are distorted because of a high transient temperature in the reflow oven, the melted and solidified metallic balls 46 can tightly connect the primary circuit board 32 and the secondary circuit board 34. Therefore, there is no problem of a poor and intermittent electrical connection found in the conventional electronic device 10.

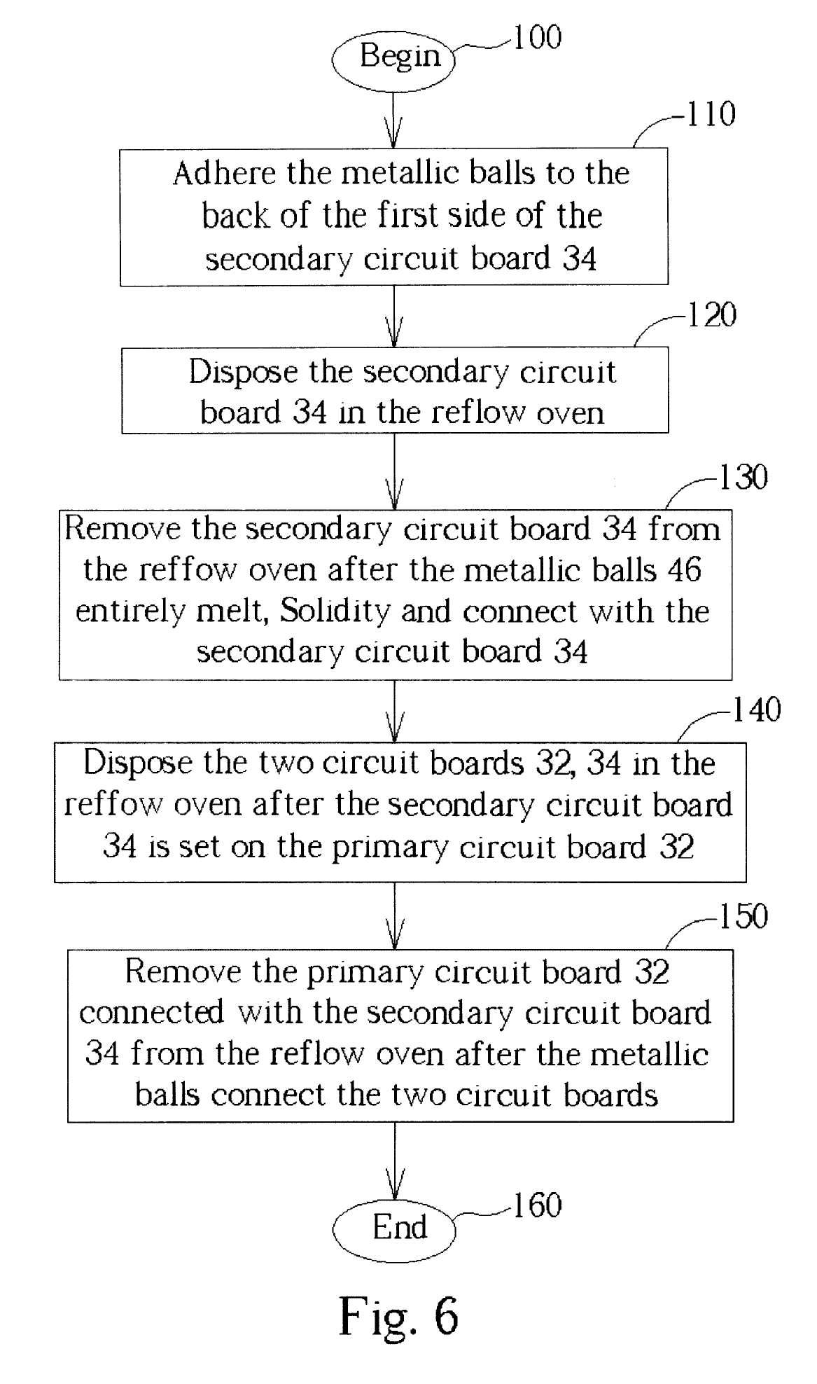

The abovementioned procedure of connecting the communication module and input/output module by metallic balls 46 is actually a method of connecting the primary circuit board 32 and the secondary circuit board 34 by the plurality of metallic balls 46. Please refer to FIG. 6. FIG. 6 is a flow chart of the abovementioned method of connecting the two circuit boards. The method comprises the following steps:

Step 100: Begin; (The plurality of electronic components 36 is set on the first side of the primary circuit board 32 and the pluralities of electronic components 38, 40 are set on the first side of the secondary circuit board 34.)

Step 110: Adhere the plurality of metallic balls 46 to the back of the first side of the secondary circuit board 34 by a flux;

Step 120: Dispose the secondary circuit board 34 and the adhered plurality of metallic balls 46 in the reflow oven;

Step 130: Remove the secondary circuit board 34 from the reflow oven after the plurality of metallic balls 46 entirely melts, solidifies, and connects with the secondary circuit board 34;

Step 140: Dispose the two circuit board 32, 34 in the reflow oven after the secondary circuit board 34 is set on the primary circuit board 32 thereby bonding the plurality of metallic balls 46 to the first side of the primary circuit board 32;

Step 150: Remove the primary circuit board 32 connected with the secondary circuit board 34 from the reflow oven after the plurality of metallic balls 46 connects the two circuit boards 32, 34;

Step 160: End.

(At this time, the secondary circuit board 34 is tightly connected with the primary circuit board 32 by the plurality of metallic balls 46, which allows the pluralities of electronic components 38, 40 on the secondary circuit board 34 to transmit data to the plurality of electronic components 36 on the primary circuit board 32, and likewise allows the plurality of electronic components 36 on the primary circuit board 32 to transmit data to the pluralities of electronic components 38, 40 on the secondary circuit board 34.

The size, number, and arrangement of the metallic balls on the secondary circuit board 34 and the interval between metallic balls could be revised for the actual requirements of the electronic device 30. Generally speaking, the abovementioned standards are implemented by referring to the ball grid array package (BGA package) for convenience of manufacture. In other words, the plurality of metallic balls is adhered to the secondary circuit board 34 with the communication module according to the existing BGA package and the actual requirements of the electronic device 30.

The pin quantity of the BGA package is much more than those of the dual in-line package (DIP) and quad flat pack package (QFP). Because the BGA package is adopted for the plurality of metallic balls 46 on the secondary circuit board 34 in the electronic device 30, all of the plurality of metallic balls 46 are not necessarily used for input/output and the surplus metallic balls can be used for the particular functionality of the communication module. Please refer to FIG. 4 again. In the FIG. 4, the metallic ball 46 in the dotted line is the output end of audio signals of the communication module. To prevent audio signals from the output end of audio signals of the communication module from being interfered with by noise, the metallic balls adjacent to the output end of audio signals provide grounding in advance during the layout procedure of the communication module.

In comparison with the conventional electronic device connecting the inner electronic modules together by connectors, the present invention electronic device connecting the communication module and input/output module by the plurality of metallic balls has the following advantages:

1) Due to the diameter of the metallic ball being under 0.75 mm, the communication module and input/output module are able to tightly connect together, meeting the needs of lightness, thinness, and compactness for modern electronic devices.

2) The pin density of the BGA package is much greater than those of the DIP and QFP so the density of the plurality of metallic balls 46 used as connectors in the present invention electronic device 30 is much greater than those of input/output ends of the connectors 20, 22 in the conventional electronic device 10. In other words, given the same area, the electronic modules in the present invention have more input/output ends than those in the conventional electronic device, and more varying circuit layouts are available the present invention electronic device 30 by using these input/output ends flexibly.

3) Compared with connectors, the plurality of metallic balls 46 is light and cheap so the weight and cost of the present invention electronic device 30 lowered effectively.

4) The primary circuit board 32 and the secondary circuit board 34 have some deformation because the present invention electronic device 30 is moved in and out of the reflow oven several times. However, the metallic balls 46 connecting the primary circuit board 32 and the secondary circuit board 34 are good at handling the curved circuit boards and are able to tightly connect the distorted primary circuit board 32 and secondary circuit board 34. This does not lead to a poor and intermittent electrical connection as it does in the conventional electronic device 10.

5) Connecting the primary circuit board 32 to the secondary circuit board 34 by melting metallic balls improves the quality of signals transmitted between the two circuit boards 32, 34.

6) The greater the number of the metallic balls, the better bonding effect between the primary circuit board 32 and the secondary circuit board 34. And, the grounding effects of signals in the present invention are superior to those of the prior art.

Additionally, the communication module packaged by the BGA has excellent electrical characteristics and thermal dissipation. After the communication module passes many complicated tests and related authorizations, mobile phone manufacturers are capable of designing an MMI PCB according to the pin description standard of input/output ends in the communication module to evolve into a vertical market structure, reducing production cost and assembly time.

Those skilled in the art will readily observe that numerous modifications and alterations of the method may be made while retaining the teachings of the invention. Accordingly, the above disclosure should be construed as limited only by the metes and bounds of the appended claims.

What is claimed is:

1. An electronic device comprising:
a primary circuit board;
a secondary circuit board fixed on the primary circuit board; and
a plurality of metallic balls electrically connected to a bottom surface of the primary circuit board and a top surface of the secondary circuit board for transmitting signals between the primary circuit board and the secondary circuit board.

2. The electronic device of claim 1 further comprising a thin layer of adhesive which is used for adhering the plurality of metallic balls to the secondary circuit board.

3. The electronic device of claim 2 wherein the adhesive is a flux.

4. The electronic device of claim 1 wherein the secondary circuit board is a circuit board with a communication module.

5. The electronic device of claim 1 wherein the secondary circuit board comprises at least an electronic component for receiving and transmitting a first type of signal, at least an electronic component for receiving and transmitting a second type of signal, and a metallic frame for dividing the electronic component for receiving and transmitting the first type of signal and the electronic component for receiving and transmitting the second type of signal into different sides of the secondary circuit board.

6. The electronic device of claim 5 wherein the first type of signal is a signal of a baseband circuit, and the second type of signal is a signal of an RF circuit.

7. The electronic device of claim 5 wherein the metallic frame has a shape that comprises two substantially parallel line segments joined at corresponding ends by a line segment that is substantially perpendicular to the two parallel line segments.

8. The electronic device of claim 5 wherein a protrusion is positioned on one side of the metallic frame.

9. The electronic device of claim 5 further comprising a metallic shielding cap covering the secondary circuit board for shielding the plurality of electronic components of the secondary circuit board to prevent the plurality of electronic components from being interfered by electromagnetic radiation.

10. The electronic device of claim 9 wherein a top of the metallic frame is capable of bonding with the metallic shielding cap when the metallic shielding cap covers the secondary circuit board.

11. The electronic device of claim 1 wherein a plurality of electronic components is set on the secondary circuit board, and the electronic device further comprises a metallic shielding cap for shielding the plurality of electronic components of the secondary circuit board to prevent the plurality of electronic components from being interfered with by electromagnetic radiation.

12. The electronic device of claim 1 wherein at least a metallic ball is used for a signal output of the secondary circuit board, and metallic balls adjacent to the signal output provide grounding.

13. The electronic device of claim 1 wherein the secondary circuit board is a printed circuit board.

14. The electronic device of claim 1 wherein the metallic balls are made of an alloy of tin and lead.

15. The electronic device of claim 1 wherein the metallic balls are made of an alloy of tin and lead having a ratio of tin to lead of 63:47.

16. The electronic device of claim 1 wherein a number of the metallic balls is not less than 145.

17. A method of connecting a primary circuit board with a secondary circuit board, at least an electronic component being set on the primary circuit board, the secondary circuit board comprising a first side and a second side, and a plurality of electronic components being set on the first side of the secondary circuit board, the method comprising:
adhering a plurality of metallic balls to the second side of the secondary circuit board;
heating and melting the plurality of metallic balls in accordance with a particular relationship between temperature and time, to make the plurality of metallic balls connect with the secondary circuit board;
bonding the plurality of metallic balls connected with the second side of the secondary circuit board to the primary circuit board; and
heating and melting the plurality of metallic balls bonded to the primary circuit board in accordance with the particular relationship between temperature and time, to make the primary circuit board connect with the secondary circuit board by means of the plurality of metallic balls;
wherein the plurality of metallic balls is used for signal transmission between the plurality of electronic components on the first side of the secondary circuit board and the electronic component on the primary circuit board.

18. The method of claim 17 wherein the secondary circuit board is a circuit board with a communication module.

19. The method of claim 17 further comprising a metallic shielding cap covering the first side of the secondary circuit board for shielding the plurality of electronic components on the first side of the secondary circuit board to prevent the plurality of electronic components from being interfered with by electromagnetic radiation.

20. The method of claim 17 wherein the plurality of electronic components on the secondary circuit board is divided into at least an electronic component for receiving and transmitting a first type of signal, and at least an electronic component for receiving and transmitting a second type of signal, and the method further comprises providing a metallic frame set on the first side of the secondary circuit board for dividing the electronic component receiving and transmitting the first type of signal and the electronic component for receiving and transmitting the second type of signal into different sides of the secondary circuit board.

21. The method of claim 20 wherein the first type of signal is a signal of a baseband circuit, and the second type of signal is a signal of an RF circuit.

22. The method of claim 20 wherein the metallic frame has a shape that comprises two substantially parallel line segments joined at corresponding ends by a line segment that is substantially perpendicular to the two parallel line segments.

23. The method of claim 20 wherein a protrusion is positioned on one side of the metallic frame.

24. The method of claim 17 wherein at least a metallic ball is used for a signal output of the secondary circuit board, and metallic balls adjacent to the signal output provide grounding.

25. The method of claim 17 wherein the secondary circuit board is a printed circuit board.

26. The method of claim 17 wherein a number of the metallic balls is not less than 145.
